(19) United States
(12) Patent Application Publication
(10) Pub. No.: US 2025/0046666 A1
(43) Pub. Date: Feb. 6, 2025

(54) UNDERFILL STRUCTURE, AND SEMICONDUCTOR CHIP CARRYING MODULE AND METHOD FOR MANUFACTURING THE SAME

(71) Applicant: ASTI GLOBAL INC., TAIWAN, Taichung City (TW)

(72) Inventor: CHIEN-SHOU LIAO, Taichung City (TW)

(21) Appl. No.: 18/739,252

(22) Filed: Jun. 10, 2024

Related U.S. Application Data
(60) Provisional application No. 63/530,071, filed on Aug. 1, 2023.

(51) Int. Cl. H01L 23/34; H01L 21/56; H01L 23/00; H01L 23/31

(52) U.S. Cl. CPC H01L 23/345; H01L 21/563; H01L 23/3157; H01L 24/16; H01L 24/32; H01L 24/73; H01L 2224/16227; H01L 2224/32225; H01L 2224/73204

(57) ABSTRACT

An underfill structure, and a semiconductor chip carrying module and a method for manufacturing the same are provided. The underfill structure includes an insulating filling material layer and a removable circuit layer. The insulating filling material layer has a plurality of through openings. The removable circuit layer is disposed on the insulating filling material layer. The removable circuit layer includes at least one removable circuit trace and a plurality of micro heaters disposed on the at least one removable circuit trace. Each of the micro heaters of the removable circuit layer corresponds to at least one of the through openings. Therefore, each of the micro heaters can be configured to solidify the insulating filling material layer between a semiconductor chip group and a circuit substrate by curing, and to solidify each conductive material between a corresponding conductive substrate pad and a conductive chip pad by curing.

### CROSS-REFERENCE TO RELATED PATENT APPLICATION

This application claims the benefit of priority to the U.S. Provisional Patent Application Ser. No. 63/530,071, filed on Aug. 1, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an underfill structure, and more particularly to an underfill structure with heating function, a semiconductor chip carrying module using the underfill structure, and a method for manufacturing the semiconductor chip carrying module using the underfill structure.

### BACKGROUND OF THE DISCLOSURE

In the related art, an underfill can be filled under a flip chip through capillary action and then cured, thereby improving the reliability of the chip soldering.

### SUMMARY OF THE DISCLOSURE

In response to the above-referenced technical inadequacy, the present disclosure provides an underfill structure with heating function, and a semiconductor chip carrying module and a method for manufacturing the semiconductor chip carrying module.

In order to solve the above-mentioned problems, one of the technical aspects adopted by the present disclosure is to provide an underfill structure with heating function, which includes an insulating filling material layer and a removable circuit layer. The insulating filling material layer has a plurality of through openings. The removable circuit layer is disposed on the insulating filling material layer without contacting the through openings. The removable circuit layer includes at least one removable circuit trace and a plurality of micro heaters disposed on the at least one removable circuit trace. Each of the micro heaters of the removable circuit layer corresponds to at least one of the through openings.

In order to solve the above-mentioned problems, another one of the technical aspects adopted by the present disclosure is to provide a semiconductor chip carrying module, which includes a circuit substrate, an underfill structure and a semiconductor chip group. The circuit substrate has a plurality of conductive substrate pads. The underfill structure is disposed on the circuit substrate. The semiconductor chip group includes a plurality of semiconductor chips disposed on the underfill structure and electrically connected to the circuit substrate. The underfill structure includes an insulating filling material layer and a removable circuit layer, the insulating filling material layer has a plurality of through openings, and the removable circuit layer is disposed on the insulating filling material layer without contacting the through openings. The removable circuit layer includes at least one removable circuit trace and a plurality of micro heaters disposed on the at least one removable circuit trace. Each of the micro heaters of the removable circuit layer corresponds to at least one of the through openings. When the at least one removable circuit trace is removed, the micro heaters carried by the at least one removable circuit trace are removed along with the at least one removable circuit trace.

In order to solve the above-mentioned problems, yet another one of the technical aspects adopted by the present disclosure is to provide a method for manufacturing a semiconductor chip carrying module, which includes: providing an underfill structure, in which the underfill structure includes an insulating filling material layer and a removable circuit layer, the insulating filling material layer has a plurality of through openings, the removable circuit layer is disposed on the insulating filling material layer without contacting the through openings, and the removable circuit layer includes at least one removable circuit trace and a plurality of micro heaters disposed on the at least one removable circuit trace; placing the underfill structure on a circuit substrate provided with a plurality of conductive substrate pads in advance; placing a plurality of semiconductor chips on the underfill structure, in which at least two conductive chip pads of each of the semiconductor chips are respectively electrically connected to two corresponding ones of the conductive substrate pads of the circuit substrate through two corresponding ones of a plurality of conductive materials; using a plurality of micro heaters of the removable circuit layer to heat the insulating filling material layer and the conductive materials, thereby allowing the semiconductor chips to be bonded on the circuit substrate through the insulating filling material layer and the conductive materials; and then removing the at least one removable circuit trace, thereby allowing the micro heaters carried by the at least one removable circuit trace to be removed along with the at least one removable circuit trace.

Therefore, in the underfill structure with heating function provided by the present disclosure, by virtue of “the insulating filling material layer having a plurality of through openings,” “the removable circuit layer being disposed on the insulating filling material layer without contacting the through openings” and “the removable circuit layer including at least one removable circuit trace and a plurality of micro heaters disposed on the at least one removable circuit trace,” each of the micro heaters can be configured to solidify the insulating filling material layer between the semiconductor chip group (including the semiconductor chips) and the circuit substrate by curing, and to solidify each conductive material between the corresponding conductive substrate pad and the conductive chip pad by curing.

Moreover, in the semiconductor chip carrying module provided by the present disclosure, by virtue of “the insulating filling material layer having a plurality of through openings,” “the removable circuit layer being disposed on the insulating filling material layer without contacting the through openings” and “the removable circuit layer including at least one removable circuit trace and a plurality of micro heaters disposed on the at least one removable circuit trace,” each of the micro heaters can be configured to solidify the insulating filling material layer between the semiconductor chip group (including the semiconductor chips) and the circuit substrate by curing, and to solidify each conductive material between the corresponding conductive substrate pad and the conductive chip pad by curing. More particularly, when the at least one removable circuit trace is removed, the micro heaters carried by the at least one removable circuit trace can be removed along with the at least one removable circuit trace.

Furthermore, in the method for manufacturing the semiconductor chip carrying module provided by the present disclosure, by virtue of “providing an underfill structure, in which the underfill structure includes an insulating filling material layer and a removable circuit layer, and the removable circuit layer includes at least one removable circuit trace and a plurality of micro heaters disposed on the at least one removable circuit trace,” “placing the underfill structure on a circuit substrate provided with a plurality of conductive substrate pads in advance,” “placing a plurality of semiconductor chips on the underfill structure” and “using a plurality of micro heaters of the removable circuit layer to heat the insulating filling material layer and the conductive materials,” each of the micro heaters can be configured to solidify the insulating filling material layer between the semiconductor chip group (including the semiconductor chips) and the circuit substrate by curing, and to solidify each conductive material between the corresponding conductive substrate pad and the conductive chip pad by curing. More particularly, when the at least one removable circuit trace is removed, the micro heaters carried by the at least one removable circuit trace can be removed along with the at least one removable circuit trace.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a semiconductor chip carrying module according to a first embodiment of the present disclosure;

FIG. 2 is a schematic cross-sectional view of an initial insulating filling material including an upper surface protective layer and a lower surface protective layer according to the first embodiment of the present disclosure;

FIG. 3 is a schematic cross-sectional view of an insulating filling material layer provided by the first embodiment of the present disclosure;

FIG. 4 is a schematic cross-sectional view of a removable circuit layer according to the first embodiment of the present disclosure;

FIG. 5 is a schematic cross-sectional view of step S100(B) of a method for manufacturing the semiconductor chip carrying module provided by the first embodiment of the present disclosure;

FIG. 6 is a schematic cross-sectional view of step S100 of the method for manufacturing the semiconductor chip carrying module provided by the first embodiment of the present disclosure;

FIG. 7 is a schematic cross-sectional view of step S102 of the method for manufacturing the semiconductor chip carrying module provided by the first embodiment of the present disclosure;

FIG. 8 is a schematic cross-sectional view of step S104 and step S106 of the method for manufacturing the semiconductor chip carrying module provided by the first embodiment of the present disclosure;

FIG. 9 is a schematic cross-sectional view of step S108 of the method for manufacturing the semiconductor chip carrying module provided by the first embodiment of the present disclosure; and

FIG. 10 is a schematic cross-sectional view of a semiconductor chip carrying module according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

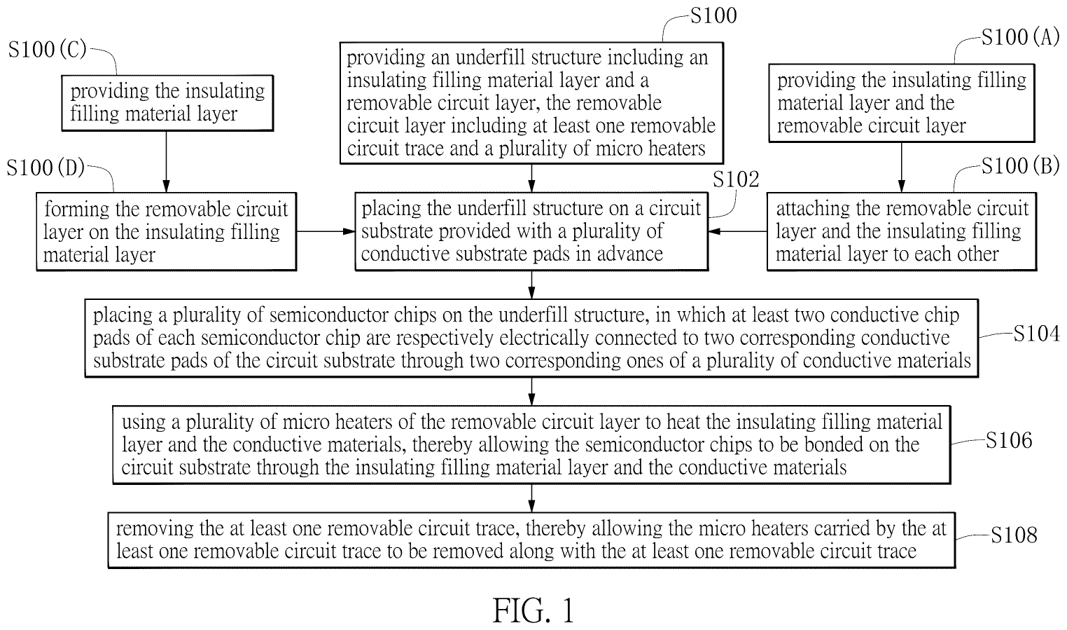

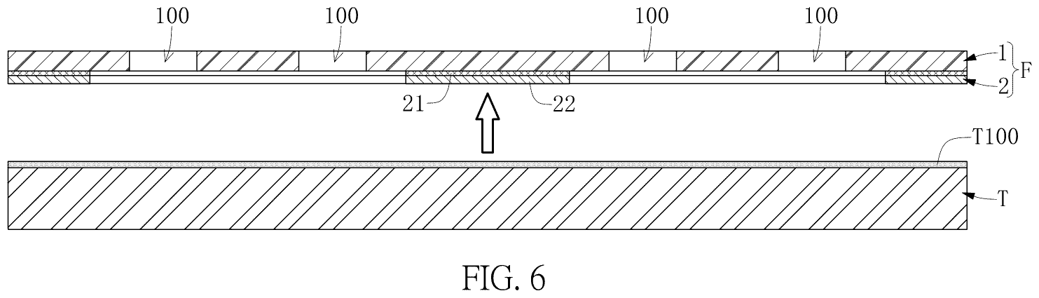

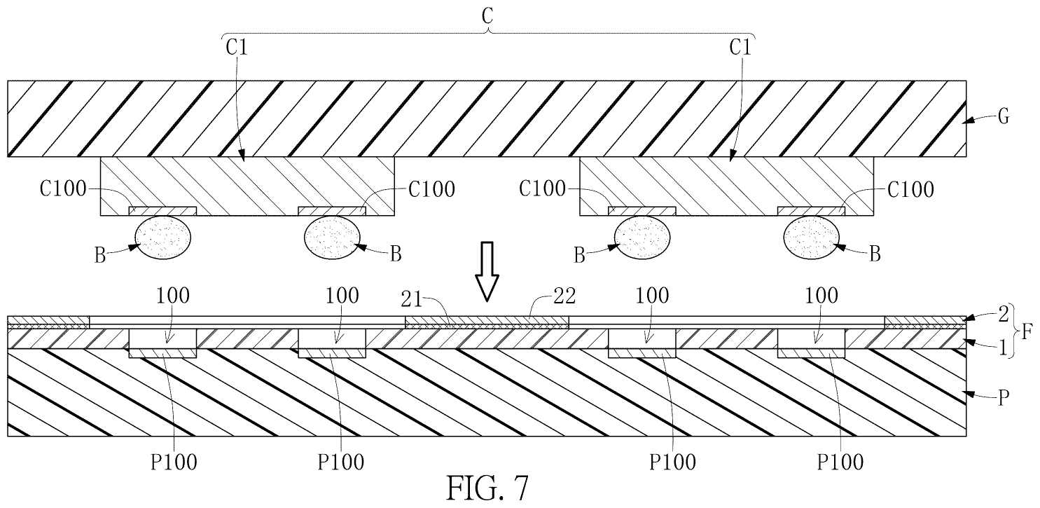

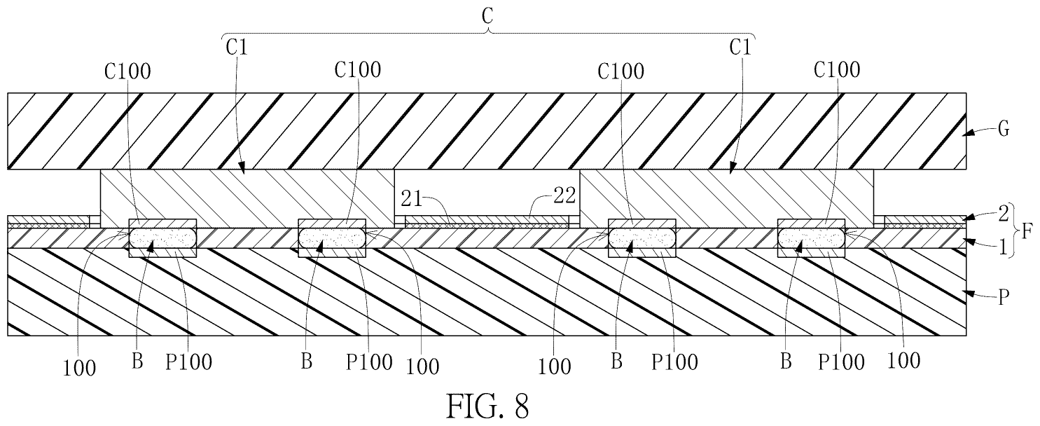

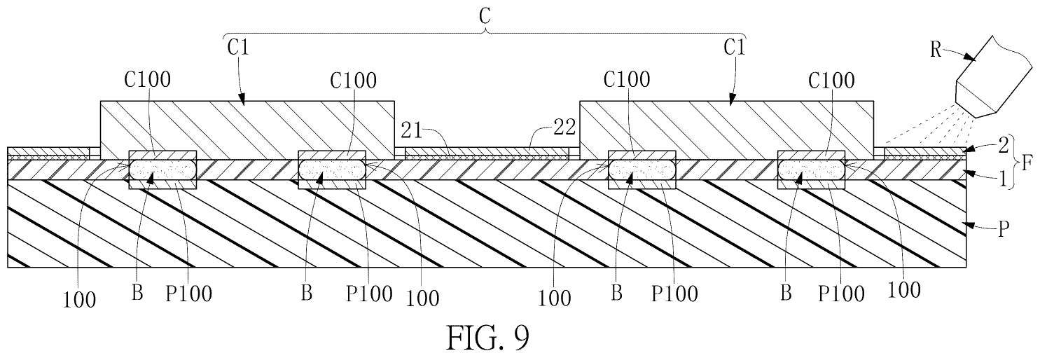

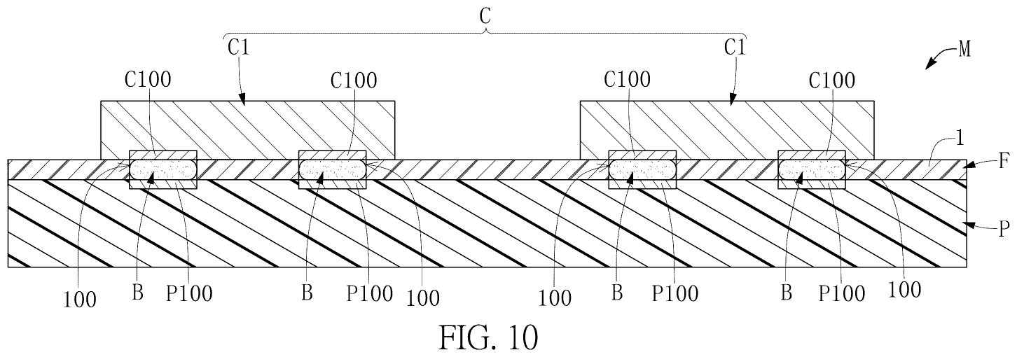

Referring to FIG. 1 to FIG. 10, a first embodiment of the present disclosure provides a method for manufacturing a semiconductor chip carrying module M, which includes: firstly, referring to FIG. 1 and FIG. 6, providing an underfill structure F (or an underfill structure F with heating function), in which the underfill structure F includes an insulating filling material layer 1 and a removable circuit layer 2, the insulating filling material layer 1 has a plurality of through openings 100, the removable circuit layer 2 is disposed on the insulating filling material layer 1 without contacting the through openings 100, and the removable circuit layer 2 includes at least one removable circuit trace 21 (or at least one removable circuit layout) and a plurality of micro heaters 22 disposed on the at least one removable circuit trace 21 (step S100); next, referring to FIG. 1, FIG. 6 and FIG. 7, placing the underfill structure F on a circuit substrate P provided with a plurality of conductive substrate pads P100 in advance (step S102); then, referring to FIG. 1, FIG. 7 and FIG. 8, placing a plurality of semiconductor chips C1 on the underfill structure F, in which at least two conductive chip pads C100 of each semiconductor chip C1 are respectively electrically connected to two corresponding conductive substrate pads P100 of the circuit substrate P through two corresponding ones of a plurality of conductive materials B (step S104); afterward, referring to FIG. 1 and FIG. 8, using (turning on) a plurality of micro heaters 22 of the removable circuit layer 2 (or driving the micro heaters 22 of the removable circuit layer 2 to generate heat) to heat the insulating filling material layer 1 and the conductive materials B, thereby allowing the semiconductor chips C1 to be bonded on the circuit substrate P through the insulating filling material layer 1 and the conductive materials B (step S106); then, referring to FIG. 1, FIG. 9 and FIG. 10, removing the at least one removable circuit trace 21, thereby allowing the micro heaters 22 carried by the at least one removable circuit trace 21 to be removed along with the at least one removable circuit trace 21 (step S108) so as to complete the manufacture of the semiconductor chip carrying module M, in which the semiconductor chip carrying module M includes the circuit substrate P, the underfill structure F excluding the removable circuit layer 2 and the semiconductor chip group C.

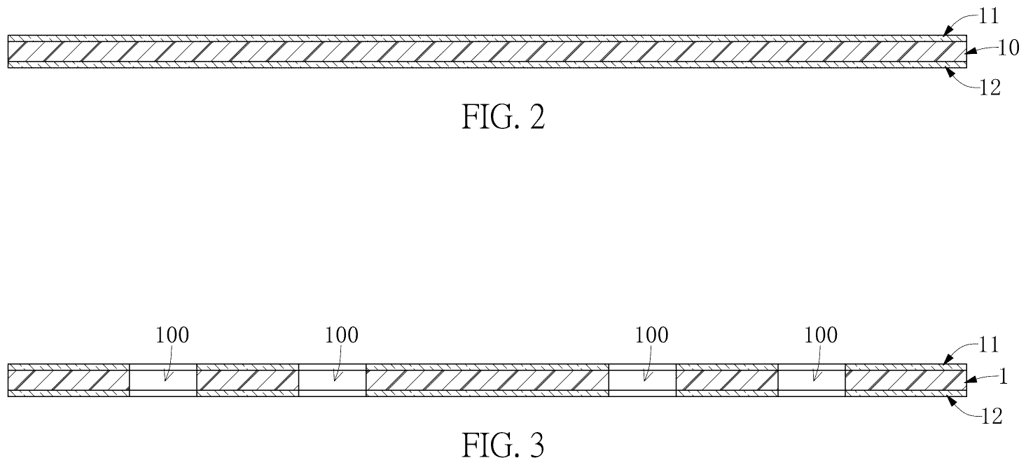

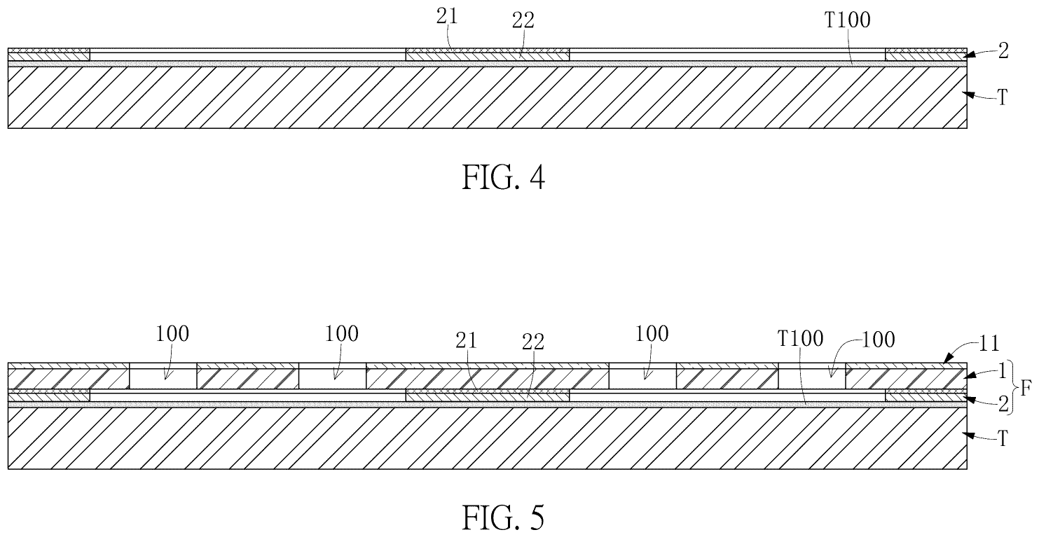

For example, referring to FIG. 1 to FIG. 6, the step S100 of providing the underfill structure F further includes: firstly, referring to FIG. 1, FIG. 3 and FIG. 4, providing the insulating filling material layer 1 and the removable circuit layer 2 (step S100(A)), and then referring to FIG. 1, FIG. 5 and FIG. 6, attaching the removable circuit layer 2 and the insulating filling material layer 1 to each other (step S100(B)). More particularly, the step S100(A) of providing the insulating filling material layer 1 further includes: referring to FIG. 1, FIG. 2 and FIG. 3, providing an initial insulating filling material 10 (such as silicone, epoxy or any kind of insulating filling material as shown in FIG. 2) including an upper surface protective layer 11 and a lower surface protective layer 12, and then forming the through openings 100 to pass through the initial insulating filling material 10 with the upper surface protective layer 11 and the lower surface protective layer 12 (as shown in FIG. 3). Moreover, the step S100(A) of providing the removable circuit layer 2 further includes: referring to FIG. 1 and FIG. 4, providing a removable circuit layer 2 including at least one removable circuit trace 21 and the micro heaters 22 on a peelable layer T100 of a temporary carrier substrate T. In addition, the step S100(B) of attaching the removable circuit layer 2 and the insulating filling material layer 1 to each other further includes: referring to FIG. 1, FIG. 3, FIG. 5 and FIG. 6, removing one of the upper surface protective layer 11 and the lower surface protective layer 12 (such as removing the lower surface protective layer 12 as shown in FIG. 5), attaching the removable circuit layer 2 to the insulating filling material layer 1 (or attaching the insulating filling material layer 1 to the removable circuit layer 2 as shown in FIG. 5), and then removing the temporary carrier substrate T with the peelable layer T100, and another one of the upper surface protective layer 11 and the lower surface protective layer 12 (such as removing the upper surface protective layer 11 as shown in FIG. 6). However, the aforementioned details are disclosed for exemplary purposes only, and are not meant to limit the scope of the present disclosure.

It should be noted that, for example, referring to FIG. 1 and FIG. 7, in the step S104 of placing the semiconductor chips C1 on the underfill structure F, the semiconductor chips C1 can be disposed on the underfill structure F through a chip carrying substrate G (such as a light-transmitting substrate or an opaque substrate). In addition, referring to FIG. 1, FIG. 9 and FIG. 10, in the step S108 of removing the at least one removable circuit trace 21, the at least one removable circuit trace 21 can be removed from the insulating filling material layer 1 through a material removal module R (such as plasma, solvent or semiconductor processing provided by the material removal module R or the material removing module). However, the aforementioned details are disclosed for exemplary purposes only, and are not meant to limit the scope of the present disclosure.

For example, in another feasible embodiment, the step S100 of providing the underfill structure F further includes: providing the insulating filling material layer 1 (step S100(C), one of the upper surface protective layer 11 and the lower surface protective layer 12 being removed in advance), and then forming the removable circuit layer 2 on the insulating filling material layer 1 (step S100(D), another one of the upper surface protective layer 11 and the lower surface protective layer 12 being removed). That is to say, according to different requirements, the insulating filling material layer 1 and the removable circuit layer 2 can be manufactured separately and then bonded together (that is to say, the removable circuit layer 2 can be directly attached to the insulating filling material layer 1 through direct attachment), or the removable circuit layer 2 can also be directly formed on the insulating filling material layer 1 by any forming method (that is to say, the removable circuit layer 2 can be disposed on the insulating filling material layer 1 through subsequent processing or forming processing), thereby eliminating the step of attaching the insulating filling material layer 1 to the removable circuit layer 2 (that is to say, the alignment and attachment steps of the insulating filling material layer 1 and the removable circuit layer 2 can be omitted). However, the aforementioned details are disclosed for exemplary purposes only, and are not meant to limit the scope of the present disclosure.

For example, as shown in FIG. 6, the insulating filling material layer 1 at least includes silicone, epoxy resin or any kind of material that can be cured by heating, and each micro heater 22 can be configured as a metal heating material (such as silver, copper, aluminum, ceramic materials), a heater circuit, a heater chip or any heating structure that can provide heat energy. It should be noted that as shown in FIG. 6, the at least one removable circuit trace 21 of the removable circuit layer 2 can continuously extend and partially surround each of the through openings 100, the at least one removable circuit trace 21 and the micro heaters 22 of the removable circuit layer 2 are not in contact with the through openings 100, and the removable circuit layer 2 can be exposed outside the insulating filling material layer 1 (that is to say, the micro heaters 22 are not in contact with the insulating filling material layer 1). In addition, as shown in FIG. 8, the underfill structure F can be configured as an underfill material (or an under filler), so that the underfill structure F can be disposed between a circuit substrate P provided with a plurality of conductive substrate pads P100 in advance and a semiconductor chip group C including a plurality of semiconductor chips C1. However, the aforementioned details are disclosed for exemplary purposes only, and are not meant to limit the scope of the present disclosure.

For example, referring to FIG. 7 and FIG. 8, when the underfill structure F and the semiconductor chip group C are sequentially stacked on the circuit substrate P, a plurality of conductive materials B (such as solder balls, solder paste or any kind of conductive material) can be disposed between the circuit substrate P and the semiconductor chip group C and respectively accommodated in the through openings 100, and at least two conductive chip pads C100 of each semiconductor chip C1 can be respectively electrically connected to two corresponding conductive substrate pads P100 of the circuit substrate P through two corresponding conductive materials B that are respectively located in two corresponding through openings 100. Moreover, as shown in FIG. 8, when the underfill structure F and the semiconductor chip group C are sequentially stacked on the circuit substrate P, each of the micro heaters 22 can be configured to provide thermal energy to the insulating filling material layer 1 for curing the insulating filling material layer 1, thereby solidifying the insulating filling material layer 1 between the semiconductor chip group C and the circuit substrate P. In addition, as shown in FIG. 8, when the underfill structure F and the semiconductor chip group C are sequentially stacked on the circuit substrate P, each of the micro heaters 22 can be configured to provide thermal energy to the corresponding at least one conductive material B for curing the corresponding at least one conductive material B, thereby solidifying the corresponding at least one conductive material B between the corresponding conductive substrate pad P100 and the corresponding conductive chip pad C100. It should be noted that as shown in FIG. 8, when the underfill structure F and the semiconductor chip group C are sequentially stacked on the circuit substrate P, the at least one removable circuit trace 21 and the micro heaters 22 of the removable circuit layer 2 are not in contact with the semiconductor chips C1. However, the aforementioned details are disclosed for exemplary purposes only, and are not meant to limit the scope of the present disclosure.

In the method of manufacturing the semiconductor chip carrying module provided by the first embodiment of the present disclosure, each of the micro heaters 22 can be configured to solidify the insulating filling material layer 1 between the semiconductor chip group C (including the semiconductor chips C1) and the circuit substrate P by curing, and to solidify each conductive material between the corresponding conductive substrate pad P100 and the conductive chip pad C100 by curing, thereby improving the structural strength (or the impact resistance) of the conductive material B and the bonding strength (or the service life) of the semiconductor chip C1. It should be noted that, when the at least one removable circuit trace 21 is removed, the micro heaters 22 carried by the at least one removable circuit trace 21 can be removed along with the at least one removable circuit trace 21.

### Second Embodiment

Referring to FIG. 8, FIG. 9 and FIG. 10, a second embodiment of the present disclosure provides a semiconductor chip carrying module M, which includes a circuit substrate P, an underfill structure F and a semiconductor chip group C. More particularly, the circuit substrate P has a plurality of conductive substrate pads P100, and the underfill structure F is disposed on the circuit substrate P. Furthermore, the semiconductor chip group C includes a plurality of semiconductor chips C1 disposed on the underfill structure F and electrically connected to the circuit substrate P. Moreover, the underfill structure F includes an insulating filling material layer 1 and a removable circuit layer 2, the insulating filling material layer 1 has a plurality of through openings 100, and the removable circuit layer 2 is disposed on the insulating filling material layer 1 without contacting the through openings 100 (for preventing the removable circuit layer 2 from contacting with the through openings 100). In addition, the removable circuit layer 2 includes at least one removable circuit trace 21 and a plurality of micro heaters 22 disposed on the at least one removable circuit trace 21, and each micro heater 22 of the removable circuit layer 2 can correspond to at least one of the through openings 100. It should be noted that as shown in FIG. 8, each of the micro heaters 22 can be configured to solidify the insulating filling material layer 1 between the semiconductor chip group C (including the semiconductor chips C1) and the circuit substrate P by curing, and to solidify each conductive material between the corresponding conductive substrate pad P100 and the conductive chip pad C100 by curing, thereby improving the structural strength (or the impact resistance) of the conductive material B and the bonding strength (or the service life) of the semiconductor chip C1.

For example, referring to FIG. 9 and FIG. 10, when the at least one removable circuit trace 21 is removed, the micro heaters 22 carried by the at least one removable circuit trace 21 are removed along with the at least one removable circuit trace 21, so that the underfill structure F provided by the second embodiment of the present disclosure can be applied to the method of manufacturing the semiconductor chip carrying module provided in the first embodiment of the present disclosure, or applied to any product that requires the underfill structure F to improve the structural strength (or the impact resistance) of the conductive material B and the bonding strength (or the service life) of the semiconductor chip C1. However, the aforementioned details are disclosed for exemplary purposes only, and are not meant to limit the scope of the present disclosure.

### Third Embodiment

Referring to FIG. 6 and FIG. 8, a third embodiment of the present disclosure provides an underfill structure F with heating function, which includes an insulating filling material layer 1 and a removable circuit layer 2. The insulating filling material layer 1 has a plurality of through openings 100, and the removable circuit layer 2 is disposed on the insulating filling material layer 1 without contacting the through openings 100. In addition, the removable circuit layer 2 includes at least one removable circuit trace 21 and a plurality of micro heaters 22 disposed on the at least one removable circuit trace 21, and each of the micro heaters 22 of the removable circuit layer 2 can correspond to at least one of the through openings 100. It should be noted that as shown in FIG. 8, each of the micro heaters 22 can be configured to solidify the insulating filling material layer 1 between the semiconductor chip group C (including the semiconductor chips C1) and the circuit substrate P by curing, and to solidify each conductive material between the corresponding conductive substrate pad P100 and the conductive chip pad C100 by curing, thereby improving the structural strength (or the impact resistance) of the conductive material B and the bonding strength (or the service life) of the semiconductor chip C1.

For example, the underfill structure F provided by the third embodiment of the present disclosure can be applied to the method of manufacturing the semiconductor chip carrying module provided in the first embodiment of the present disclosure, applied to the semiconductor chip carrying module M provided by the second embodiment of the present disclosure, or applied to any product that requires the underfill structure F to improve the structural strength (or the impact resistance) of the conductive material B and the bonding strength (or the service life) of the semiconductor chip C1. However, the aforementioned details are disclosed for exemplary purposes only, and are not meant to limit the scope of the present disclosure.

### Beneficial Effects of the Embodiments

In conclusion, in the underfill structure F with heating function provided by the present disclosure, by virtue of “the insulating filling material layer 1 having a plurality of through openings 100,” “the removable circuit layer 2 being disposed on the insulating filling material layer 1 without contacting the through openings 100” and “the removable circuit layer 2 including at least one removable circuit trace 21 and a plurality of micro heaters 22 disposed on the at least one removable circuit trace 21,” each of the micro heaters 22 can be configured to solidify the insulating filling material layer 1 between the semiconductor chip group C (including the semiconductor chips C1) and the circuit substrate P by curing, and to solidify each conductive material between the corresponding conductive substrate pad P100 and the conductive chip pad C100 by curing.

Furthermore, in the semiconductor chip carrying module M provided by the present disclosure, by virtue of “the insulating filling material layer 1 having a plurality of through openings 100,” “the removable circuit layer 2 being disposed on the insulating filling material layer 1 without contacting the through openings 100” and “the removable circuit layer 2 including at least one removable circuit trace 21 and a plurality of micro heaters 22 disposed on the at least one removable circuit trace 21,” each of the micro heaters 22 can be configured to solidify the insulating filling material layer 1 between the semiconductor chip group C (including the semiconductor chips C1) and the circuit substrate P by curing, and to solidify each conductive material between the corresponding conductive substrate pad P100 and the conductive chip pad C100 by curing. More particularly, when the at least one removable circuit trace 21 is removed, the micro heaters 22 carried by the at least one removable circuit trace 21 can be removed along with the at least one removable circuit trace 21.

Moreover, in the method for manufacturing the semiconductor chip carrying module M provided by the present disclosure, by virtue of “providing an underfill structure F, in which the underfill structure F includes an insulating filling material layer 1 and a removable circuit layer 2, and the removable circuit layer 2 includes at least one removable circuit trace 21 and a plurality of micro heaters 22 disposed on the at least one removable circuit trace 21,” “placing the underfill structure F on a circuit substrate P provided with a plurality of conductive substrate pads P100 in advance,” “placing a plurality of semiconductor chips C1 on the underfill structure F” and “using a plurality of micro heaters 22 of the removable circuit layer 2 to heat the insulating filling material layer 1 and the conductive materials B,” each of the micro heaters 22 can be configured to solidify the insulating filling material layer 1 between the semiconductor chip group C (including the semiconductor chips C1) and the circuit substrate P by curing, and to solidify each conductive material between the corresponding conductive substrate pad P100 and the conductive chip pad C100 by curing. More particularly, when the at least one removable circuit trace 21 is removed, the micro heaters 22 carried by the at least one removable circuit trace 21 can be removed along with the at least one removable circuit trace 21.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An underfill structure with heating function, comprising:
an insulating filling material layer having a plurality of through openings; and
a removable circuit layer disposed on the insulating filling material layer without contacting the through openings;
wherein the removable circuit layer includes at least one removable circuit trace and a plurality of micro heaters disposed on the at least one removable circuit trace;
wherein each of the micro heaters of the removable circuit layer corresponds to at least one of the through openings.

2. The underfill structure according to claim 1,
wherein the insulating filling material layer at least includes silicone or epoxy resin;
wherein the underfill structure is configured as an underfill material, so that the underfill structure is disposed between a circuit substrate provided with a plurality of conductive substrate pads in advance and a semiconductor chip group including a plurality of semiconductor chips;
wherein, when the underfill structure and the semiconductor chip group are sequentially stacked on the circuit substrate, a plurality of conductive materials are disposed between the circuit substrate and the semiconductor chip group and respectively accommodated in the through openings, and at least two conductive chip pads of each of the semiconductor chips are respectively electrically connected to two corresponding ones of the conductive substrate pads of the circuit substrate through two corresponding ones of the conductive materials that are respectively located in two corresponding ones of the through openings;
wherein, when the underfill structure and the semiconductor chip group are sequentially stacked on the circuit substrate, each of the micro heaters is configured to provide thermal energy to the insulating filling material layer for curing the insulating filling material layer, thereby solidifying the insulating filling material layer between the semiconductor chip group and the circuit substrate;
wherein, when the underfill structure and the semiconductor chip group are sequentially stacked on the circuit substrate, each of the micro heaters is configured to provide thermal energy to corresponding at least one of the conductive materials for curing the corresponding at least one conductive material, thereby solidifying the corresponding at least one conductive material between a corresponding one of the conductive substrate pads and a corresponding one of the conductive chip pads;
wherein the at least one removable circuit trace of the removable circuit layer continuously extends and partially surrounds each of the through openings;
wherein the at least one removable circuit trace and the micro heaters of the removable circuit layer are not in contact with the through openings, and the micro heaters are not in contact with the insulating filling material layer;
wherein, when the underfill structure and the semiconductor chip group are sequentially stacked on the circuit substrate, the at least one removable circuit trace and the micro heaters of the removable circuit layer are not in contact with the semiconductor chips;
wherein each of the micro heaters is configured as a metal heating material, a heater circuit or a heater chip;
wherein the removable circuit layer is exposed outside the insulating filling material layer;
wherein the removable circuit layer is disposed on the insulating filling material layer through forming processing or direct attachment.

3. The underfill structure according to claim 1,
wherein the insulating filling material layer at least includes silicone or epoxy resin;
wherein the underfill structure is configured as an underfill material applied to a circuit substrate provided and a semiconductor chip group;
wherein the at least one removable circuit trace of the removable circuit layer continuously extends and partially surrounds each of the through openings;
wherein the at least one removable circuit trace and the micro heaters of the removable circuit layer are not in contact with the through openings, and the micro heaters are not in contact with the insulating filling material layer;
wherein each of the micro heaters is configured as a metal heating material, a heater circuit or a heater chip;
wherein the removable circuit layer is exposed outside the insulating filling material layer;
wherein the removable circuit layer is disposed on the insulating filling material layer through forming processing or direct attachment.

4. A semiconductor chip carrying module, comprising:
a circuit substrate having a plurality of conductive substrate pads;
an underfill structure disposed on the circuit substrate; and
a semiconductor chip group including a plurality of semiconductor chips disposed on the underfill structure and electrically connected to the circuit substrate;
wherein the underfill structure includes an insulating filling material layer and a removable circuit layer, the insulating filling material layer has a plurality of through openings, and the removable circuit layer is disposed on the insulating filling material layer without contacting the through openings;
wherein the removable circuit layer includes at least one removable circuit trace and a plurality of micro heaters disposed on the at least one removable circuit trace;
wherein each of the micro heaters of the removable circuit layer corresponds to at least one of the through openings;
wherein, when the at least one removable circuit trace is removed, the micro heaters carried by the at least one removable circuit trace are removed along with the at least one removable circuit trace.

5. The semiconductor chip carrying module according to claim 4,
wherein the insulating filling material layer at least includes silicone or epoxy resin;
wherein the underfill structure is configured as an underfill material, so that the underfill structure is disposed between the circuit substrate and the semiconductor chip group;
wherein, when the underfill structure and the semiconductor chip group are sequentially stacked on the circuit substrate, a plurality of conductive materials are disposed between the circuit substrate and the semiconductor chip group and respectively accommodated in the through openings, and at least two conductive chip pads of each of the semiconductor chips are respectively electrically connected to two corresponding ones of the conductive substrate pads of the circuit substrate through two corresponding ones of the conductive materials that are respectively located in two corresponding ones of the through openings;
wherein, when the underfill structure and the semiconductor chip group are sequentially stacked on the circuit substrate, each of the micro heaters is configured to provide thermal energy to the insulating filling material layer for curing the insulating filling material layer, thereby solidifying the insulating filling material layer between the semiconductor chip group and the circuit substrate;
wherein, when the underfill structure and the semiconductor chip group are sequentially stacked on the circuit substrate, each of the micro heaters is configured to provide thermal energy to corresponding at least one of the conductive materials for curing the corresponding at least one conductive material, thereby solidifying the corresponding at least one conductive material between a corresponding one of the conductive substrate pads and a corresponding one of the conductive chip pads;
wherein the at least one removable circuit trace of the removable circuit layer continuously extends and partially surrounds each of the through openings;
wherein the at least one removable circuit trace and the micro heaters of the removable circuit layer are not in contact with the through openings, and the micro heaters are not in contact with the insulating filling material layer;
wherein, when the underfill structure and the semiconductor chip group are sequentially stacked on the circuit substrate, the at least one removable circuit trace and the micro heaters of the removable circuit layer are not in contact with the semiconductor chips;
wherein each of the micro heaters is configured as a metal heating material, a heater circuit or a heater chip;
wherein the removable circuit layer is exposed outside the insulating filling material layer;
wherein the removable circuit layer is disposed on the insulating filling material layer through forming processing or direct attachment.

6. A method for manufacturing a semiconductor chip carrying module, comprising:
providing an underfill structure, wherein the underfill structure includes an insulating filling material layer and a removable circuit layer, the insulating filling material layer has a plurality of through openings, the removable circuit layer is disposed on the insulating filling material layer without contacting the through openings, and the removable circuit layer includes at least one removable circuit trace and a plurality of micro heaters disposed on the at least one removable circuit trace;
placing the underfill structure on a circuit substrate provided with a plurality of conductive substrate pads in advance;
placing a plurality of semiconductor chips on the underfill structure, wherein at least two conductive chip pads of each of the semiconductor chips are respectively electrically connected to two corresponding ones of the conductive substrate pads of the circuit substrate through two corresponding ones of a plurality of conductive materials;
using a plurality of micro heaters of the removable circuit layer to heat the insulating filling material layer and the conductive materials, thereby allowing the semiconductor chips to be bonded on the circuit substrate through the insulating filling material layer and the conductive materials; and
removing the at least one removable circuit trace, thereby allowing the micro heaters carried by the at least one removable circuit trace to be removed along with the at least one removable circuit trace.

7. The method according to claim 6,
wherein the step of providing the underfill structure further includes: providing the insulating filling material layer and the removable circuit layer, and then attaching the removable circuit layer and the insulating filling material layer to each other;
wherein the step of providing the insulating filling material layer further includes: providing an initial insulating filling material including an upper surface protective layer and a lower surface protective layer, and then forming the through openings to pass through the initial insulating filling material with the upper surface protective layer and the lower surface protective layer;
wherein the step of attaching the removable circuit layer and the insulating filling material layer to each other further includes: removing one of the upper surface protective layer and the lower surface protective layer, attaching the removable circuit layer to the insulating filling material layer, and then removing another one of the upper surface protective layer and the lower surface protective layer;
wherein, in the step of placing the semiconductor chips on the underfill structure, the semiconductor chips are disposed on the underfill structure through a chip carrying substrate;
wherein, in the step of removing the at least one removable circuit trace, the at least one removable circuit trace is removed from the insulating filling material layer through a material removal module.

8. The method according to claim 6,
wherein the step of providing the underfill structure further includes: providing the insulating filling material layer, and then forming the removable circuit layer on the insulating filling material layer;
wherein, in the step of placing the semiconductor chips on the underfill structure, the semiconductor chips are disposed on the underfill structure through a chip carrying substrate;
wherein, in the step of removing the at least one removable circuit trace, the at least one removable circuit trace is removed from the insulating filling material layer through a material removal module.

9. The method according to claim 6,
wherein the insulating filling material layer at least includes silicone or epoxy resin;
wherein the underfill structure is configured as an underfill material, so that the underfill structure is disposed between the circuit substrate and a semiconductor chip group including the semiconductor chips;
wherein, when the underfill structure and the semiconductor chip group are sequentially stacked on the circuit substrate, the conductive materials are disposed between the circuit substrate and the semiconductor chip group and respectively accommodated in the through openings, and at least two of the conductive chip pads of each of the semiconductor chips are respectively electrically connected to two corresponding ones of the conductive substrate pads of the circuit substrate through two corresponding ones of the conductive materials that are respectively located in two corresponding ones of the through openings;
wherein, when the underfill structure and the semiconductor chip group are sequentially stacked on the circuit substrate, each of the micro heaters is configured to provide thermal energy to the insulating filling material layer for curing the insulating filling material layer, thereby solidifying the insulating filling material layer between the semiconductor chip group and the circuit substrate;
wherein, when the underfill structure and the semiconductor chip group are sequentially stacked on the circuit substrate, each of the micro heaters is configured to provide thermal energy to corresponding at least one of the conductive materials for curing the corresponding at least one conductive material, thereby solidifying the corresponding at least one conductive material between a corresponding one of the conductive substrate pads and a corresponding one of the conductive chip pads;
wherein the at least one removable circuit trace of the removable circuit layer continuously extends and partially surrounds each of the through openings;
wherein the at least one removable circuit trace and the micro heaters of the removable circuit layer are not in contact with the through openings, and the micro heaters are not in contact with the insulating filling material layer;
wherein, when the underfill structure and the semiconductor chip group are sequentially stacked on the circuit substrate, the at least one removable circuit trace and the micro heaters of the removable circuit layer are not in contact with the semiconductor chips;
wherein each of the micro heaters is configured as a metal heating material, a heater circuit or a heater chip;
wherein the removable circuit layer is exposed outside the insulating filling material layer;
wherein the removable circuit layer is disposed on the insulating filling material layer through forming processing or direct attachment.

10. A semiconductor chip carrying module manufactured by the method as claimed in claim 6, the semiconductor chip carrying module including the circuit substrate, the semiconductors chips, and the underfill structure without the removable circuit layer.
